(19) United States
(12) Patent Application Publication
(10) Pub. No.: US 2026/0118779 A1
(43) Pub. Date: Apr. 30, 2026

(54) MIRROR SYSTEM, METHOD FOR OPERATING A MIRROR SYSTEM AND PROJECTION LENS OF A MICROLITHOGRAPHIC PROJECTION EXPOSURE APPARATUS

(71) Applicant: Carl Zeiss SMT GmbH, Oberkochen (DE)

(72) Inventors: Joerg Starzmann, Oberkochen (DE); Julian ZIPS, Augsburg (DE); Philipp Bartsch, Oberkochen (DE); Thomas MONZ, Schlierbach (DE); Martin BICKERT, Vallendar (DE)

(21) Appl. No.: 19/430,431

(22) Filed: Dec. 23, 2025

Related U.S. Application Data
(63) Continuation of application No. PCT/EP2024/065417, filed on Jun. 5, 2024.

(30) Foreign Application Priority Data
Jun. 30, 2023 (DE) 102023206188.0

(51) Int. Cl. G03F 7/00

(52) U.S. Cl. CPC G03F 7/70891; G03F 7/70316; G03F 7/70825

(57) ABSTRACT

A mirror system comprises an EUV mirror. The EUV mirror comprises a mirror body and an optical surface with high EUV radiation reflectivity. The mirror system further comprises a frame structure which carries the mirror body, a fluid channel for a temperature control fluid, the fluid channel extending in a structure body of the mirror system, and a feed line for supplying the temperature control fluid to the fluid channel. The feed line has a temperature sensor for the temperature control fluid temperature. The temperature sensor is arranged outside of the cross section of the feed line. A method for operating a mirror system and a projection lens of a microlithography projection exposure apparatus are disclosed.

### CROSS-REFERENCE TO RELATED APPLICATIONS

The present application is a continuation of, and claims benefit under 35 USC 120 to, international application No. PCT/EP2024/065417, filed Jun. 5, 2024, which claims benefit under 35 USC 119 of German Application No. 10 2023 206 188.0, filed Jun. 30, 2023. The entire disclosure of each of these applications is incorporated by reference herein.

### FIELD

The disclosure relates to a mirror system, to a method for operating a mirror system, to a projection lens of a microlithography projection exposure apparatus, and to a microlithography projection exposure apparatus.

### BACKGROUND

Microlithography projection exposure apparatuses are typically utilized for the production of integrated circuits with relatively small structures. In some cases, a photomask illuminated by extreme ultraviolet radiation (EUV radiation) is imaged on a lithography object to transfer the mask structure to the lithography object.

The projection exposure apparatus can comprise a plurality of EUV mirrors which comprise an optical surface at which the EUV radiation is reflected. The EUV mirrors typically have a relatively precisely defined shape and are relatively precisely positioned so that the image representation of the mask on the lithography object is of sufficient quality.

Some of the EUV radiation incident on the optical surface of the mirror is reflected and some is absorbed. The absorbed portion of the EUV radiation can bring about mirror body heating. In general, temperature changes of a body are accompanied by a thermal deformation. This is usually unwanted in the case of microlithographic projection exposure apparatus mirrors because the wavefront of the EUV radiation reflected at the optical surface is usually modified when the geometric shape of the mirror changes. This usually leads to a reduction in the imaging quality.

In order to influence the mirror system temperature in a desired manner, it is possible to provide mirror system structures with fluid channels through which a temperature control fluid is guided. With regards to relatively precisely setting the thermal state of the mirror system structures, knowledge of the temperature control fluid temperature upon entry into the structure is desirable.

### SUMMARY

The disclosure seeks to provide a mirror system, a method for operating a mirror system, a projection lens of a microlithographic projection exposure apparatus, and a microlithographic projection exposure apparatus, for which the temperature of a temperature control fluid supplied to a mirror system structure can be determined with relatively good accuracy.

A mirror system according to the disclosure can comprise an EUV mirror, a frame structure which carries the mirror body, a fluid channel for a temperature control fluid, the fluid channel extending within a structure body of the mirror system, and a feed line for supplying a temperature control fluid to the fluid channel. The EUV mirror comprises a mirror body and an optical surface with high EUV radiation reflectivity formed on the mirror body. The feed line is provided with a temperature sensor for the temperature control fluid temperature. The temperature sensor is arranged outside of the cross section of the feed line.

The disclosure involves the insight that sufficiently accurate ascertainment of the temperature control fluid temperature is not easy under the boundary conditions that are observed during the operation of a microlithographic projection exposure apparatus. It has been found that conventional temperature sensors, where a sensor element projects into the fluid channel, tend to interfere with the temperature control fluid flow and cause turbulence. Such turbulence is undesirable because it can be transferred to the mirror system structure and can trigger vibrations. The disclosure therefore proposes the use of a temperature sensor arranged outside of the cross section of the feed line. A further issue arising is that the measured values recorded by the temperature sensor can be influenced by structures in the temperature control fluid surroundings. For instance, an integration of temperature sensor in the structure body could lead to the measurement result being falsified by quantities of heat stored there. The disclosure therefore proposes the arrangement of the temperature sensor in a feed line which extends to the fluid channel.

The structure body within which the fluid channel extends can be the mirror body of the EUV mirror. In an embodiment, the structure body is the frame structure which carries the mirror body. In an embodiment, the structure body is a sensor frame structure. The sensor frame structure can be a constituent part of the mirror system and, for instance, carry sensors used to obtain information about the position of the mirror body. It is also possible for the disclosure to be applied in parallel to a plurality of structure bodies of a mirror system.

In variants, the temperature control fluid supplied by way of the feed line can serve to bring the structure body to a desired temperature. The structure can be either heated or cooled, depending on the relationship between the temperature control fluid temperature and the structure body temperature. The temperature control fluid can be a temperature control liquid, especially water. To keep disturbances triggered by turbulence to a minimum, it is desirable for the volumetric flow rate of the temperature control fluid to be relatively low. For example, the volumetric flow rate can be less than 2 l/min, such as less than 1 l/min.

The fluid channel might fan open such that a plurality of fluid channel portions extend in parallel with one another within the structure. An input manifold used to distribute the temperature control fluid coming from the feed line among the fluid channel portions may be formed between the feed line and the fluid portions. The input manifold might be formed within the structure body such that the temperature control fluid enters the structure body through a single input opening. The temperature sensor can be arranged at a distance of at least 5 cm, such as at least 20 cm, for example at least 50 cm, from the input manifold. This distance may also be observed if the input manifold is arranged outside of the structure body. The fluid channel portions can be connected to a return line via an output manifold. The temperature control fluid can be circulated via the feed line, the fluid channel and a return line.

The feed line can have a tube wall that encloses the interior. The temperature sensor can be formed such that the feed line tube wall is not interrupted in the region of the temperature sensor. The temperature sensor can be arranged outside the tube wall. The temperature sensor can comprise a sensor element which is in physical contact with the tube wall. The temperature sensor can be designed such that an electrical measurement signal is derived from the sensor element temperature. The measurement signal can be transferred to a control unit of the mirror system in order to be processed there.

The measured temperature values can be falsified as a result of heat being dissipated from the tube wall via the temperature sensor itself. In the case of a temperature sensor which is in physical contact with the tube wall, the physical contact can be restricted to a circumferential portion of the feed line. The other circumferential portion, which is not in contact with the temperature sensor, may extend over at least 180°, such as over at least 270°. Thus, the falsification of measured temperature values can be reduced significantly in comparison with, for example, a temperature sensor which is connected to the feed line via a sleeve extending around the entire circumference of the feed line.

The temperature sensor may comprise a housing which is adhesively bonded to the tube wall. A sensor element of the temperature sensor can be thermally coupled to the housing via a thermally conductive paste, with the result that a good heat transmission sets in between the tube wall and the sensor element.

For a temperature sensor in physical contact with the tube wall, the heat transfer between the temperature control fluid and the temperature sensor can be implemented via the tube wall. In this case, the measured temperature value generally depends on the temperature distribution of the temperature control fluid over the cross section of the feed line. Peripheral components of the temperature control fluid in the vicinity of the tube wall may have a greater influence on the measured temperature value than central components of the temperature control fluid in the centre of the feed line, which have a greater distance from the tube wall.

A large temperature gradient over the cross section of the temperature control fluid in the feed line is generally undesirable in relation to the validity of the measured temperature values. Measured temperature values primarily influenced by the temperature of peripheral components of the temperature control fluid in that case have no optimal validity with regards to the average temperature of the temperature control fluid in this portion of the feed line. The disclosure proposes the arrangement of the temperature sensor in a portion of the feed line in which the temperature gradient within the temperature control fluid is small over the cross section of the feed line. It is desirable in this regard if the temperature control fluid experiences mixing over the cross section, for instance as is the case in the region of a deflection in the feed line. For this reason, the temperature sensor may be arranged slightly downstream of a deflection in the feed line. Slightly downstream refers to a distance between the deflection and the temperature sensor being less than 10 cm, such as less than 5 cm, for example less than 2 cm. In contrast thereto, a laminar flow, which is accompanied by a greater temperature gradient of the temperature control fluid over the cross section, usually sets in in long straight portions of the feed line.

It has been found that measured values recorded by the temperature sensor might be significantly falsified if other structures that absorb heat from the tube wall are arranged in the vicinity of the temperature sensor. For instance, such heat-conducting structures can be tube holders or even the mirror body itself. The temperature sensor can be arranged in a portion of the feed line which is without heat-conducting structures. The distance between the temperature sensor and the closest heat-conducting structure, as measured along the feed line, can be greater than 20 mm, such as greater than 50 mm, for example greater than 100 mm.

The temperature gradient which forms over the cross section of the feed line in the case of a laminar flow is the result of, inter alia, heat being transferred between peripheral components of the temperature control fluid and the tube wall. With regards to the disclosure, it is desirable for this heat transfer to be kept low. Thus, the feed line may comprise portions in which the tube wall is provided with a thermal insulation. The thermal insulation can be designed such that it causes no outgassing under the vacuum conditions found in the microlithographic projection exposure apparatus. For example, an insulation can be formed in long straight portions of the feed line. In general, the tube wall should not have a thermal insulation in the region of the temperature sensor so that the heat transfer between the temperature control fluid and the temperature sensor is as unimpeded as possible. The temperature sensor can be arranged downstream of a portion of the feed line in which the feed line is provided with a thermal insulation.

A mixer bringing about mixing of the temperature control fluid over its cross section may be arranged in the feed line in order to prevent a strong temperature gradient from forming due to a relatively long portion of laminar flow. The mixer can be designed such that the temperature control fluid is mixed over the cross section without turbulence being generated. Mixers that manage this are known from the chemical industry, for example. The mixer may comprise mixing structures which project into the interior of the feed line and are matched to one another such that no turbulence arises.

The disclosure assumes that complete homogeneity of the temperature distribution over the temperature control fluid cross section will remain unattainable. Thus, a deviation remains between the temperature sensor measured values, which are primarily influenced by the peripheral components of the temperature control fluid, and the average temperature over the cross section of the temperature control fluid. The disclosure encompasses a first calculation method in which an average value of the temperature is calculated starting from measured temperature values recorded by the temperature sensor; the average value of the temperature relates to the average temperature of the temperature control fluid over the cross section of the temperature control fluid in the region of the temperature sensor. The calculation may incorporate measured temperature values from the temperature sensor and a first model relating to the distribution of the temperature over the cross section of the temperature control fluid. The control unit of the mirror system can use a corrected temperature value, which was ascertained by applying such a first calculation method. A table allowing corrected temperature values to be read for specific measured temperature values can be stored in a memory module of the control unit.

A measured temperature value relating to a portion of the feed line in which the temperature sensor is arranged may not automatically be representative of the temperature of the temperature control fluid upon entry in the mirror body if the temperature sensor is at a distance from the mirror body. The disclosure encompasses a second calculation method in which a derived temperature value is ascertained starting from a temperature value related to the position of the temperature sensor or a measured temperature value. The derived temperature value represents the temperature of the temperature control fluid upon entrance in the mirror body. The calculation may incorporate a measured temperature value related to the position of the temperature sensor and a second model regarding the spread of temperature between the temperature sensor position and the mirror body entrance. The second calculation method may be applied in addition or as an alternative to the first calculation method. The derived temperature value can be ascertained on the basis of a table stored in the memory module.

The mirror system may comprise a first temperature sensor and a second temperature sensor, especially for redundancy purposes. The temperature sensors may each be designed to measure the temperature control fluid temperature in the feed line. The temperature sensors might be spatially adjacent to one another, with the result that the recorded measured temperature values are equivalent. In an embodiment, the first temperature sensor and the second temperature sensor are arranged in a shared housing. The first temperature sensor and the second temperature sensor might be operated in a master/slave configuration, with the result that the measured values from the second temperature sensor only become relevant if the first temperature sensor suffers an outage. The disclosure also encompasses temperature sensors operating on a contactless principle, in which there is no physical contact between the tube wall and the temperature sensor.

The measured temperature value can be processed in the control unit in order to create control signals used to control the operation of the mirror system. For instance, the control signals can be used to control a piece of temperature control equipment used to supply heat to or withdraw heat from the temperature control fluid before the temperature control fluid enters the fluid channel of the structure body. The control signals can be used to control other parameters of the mirror system, for instance actuators used to modify the mechanical position of the mirror body and/or heating/cooling equipment used to influence the temperature of the mirror body.

If a second measured temperature value related to the temperature of the temperature control fluid following its exit from the mirror body is available in the control unit, then the temperature difference can be used to deduce the quantity of heat absorbed by the temperature control fluid during its passage through the mirror surface. A degradation of the optical surface generally leads to change in this quantity of heat since the proportion of reflected EUV radiation is reduced and, by contrast, the proportion of absorbed EUV radiation, which generally leads to the mirror body heating up, is increased. Conclusions regarding the state of the optical surface can be drawn by evaluating the temperature difference between the first measured temperature value and the second measured temperature value. For instance, such information can be used within the scope of predictive maintenance methods.

The disclosure also relates to a projection lens having a plurality of EUV mirrors used to image a photomask in an image plane. At least one of the EUV mirrors can be an EUV mirror of a mirror system according to the disclosure. The disclosure also relates to a microlithographic projection exposure apparatus having such a projection lens.

The disclosure also relates to a method for operating a mirror system, wherein an EUV mirror comprises a mirror body and an optical surface with high EUV radiation reflectivity formed on the mirror body, and wherein the mirror body is carried by a frame structure. A temperature control fluid is guided through a fluid channel which extends through a structure body of the mirror system. The temperature control fluid is supplied to the fluid channel through a feed line. A temperature sensor is used to record a measured temperature value for the temperature control fluid temperature in a portion of the feed line. The temperature sensor is arranged outside of the cross section of the feed line.

The disclosure encompasses developments of the method with features that are described in the context of the mirror system according to the disclosure. The disclosure encompasses developments of the mirror system with features that are described in the context of the method according to the disclosure.

The disclosure is described by way of examples below on the basis of certain embodiments by reference to the accompanying drawings.

### BRIEF DESCRIPTION OF THE DRAWINGS

In the figures:

FIG. 1: shows an embodiment of a projection exposure apparatus according to the disclosure;

FIG. 2: shows a schematic illustration of a mirror system according to the disclosure;

FIG. 3: shows a temperature distribution at a first position in the feed line;

FIG. 4: shows a temperature distribution at a second position in the feed line;

FIG. 5: shows the view according to FIG. 2 in an alternative embodiment of the disclosure;

FIG. 6: shows a temperature profile along a portion of the feed line;

FIG. 7: shows a portion of a feed line according to the disclosure;

FIG. 8: shows a portion of a feed line according to the disclosure in an alternative embodiment of the disclosure;

FIG. 9: shows a sectional illustration of a feed line with a temperature sensor according to the disclosure;

FIG. 10: shows the embodiment according to FIG. 9 from a different perspective;

FIG. 11: shows the view according to FIG. 9 in an alternative embodiment of the disclosure;

FIG. 12: shows an alternative embodiment of an EUV mirror according to the disclosure.

### DETAILED DESCRIPTION

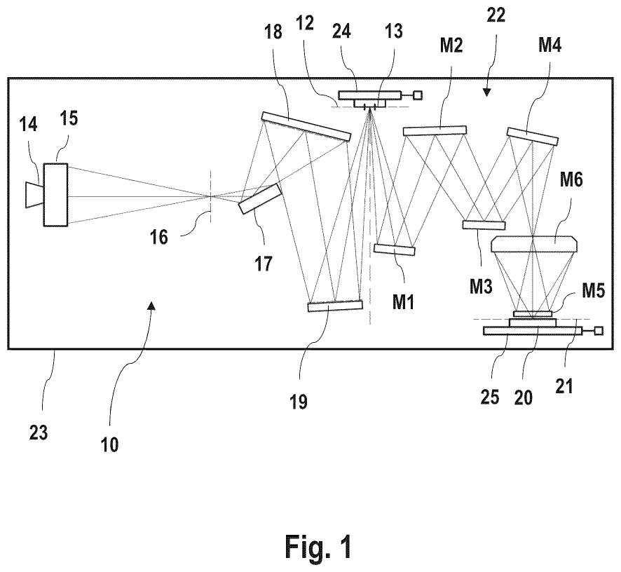

FIG. 1 schematically shows a microlithographic EUV projection exposure apparatus. The projection exposure apparatus comprises an exposure beam source 14, an illumination system 10 and a projection lens 22, which are operated together in a vacuum chamber 23. Negative pressure is prevalent in the vacuum chamber 23 during the operation of the EUV projection exposure apparatus.

The exposure beam source 14 creates electromagnetic radiation in the EUV range, i.e. at a wavelength of between 5 nm and 30 nm for example. The exposure radiation emanating from the exposure beam source 14 is focused on an intermediate focal plane 16 by way of a collector 15. Exposure radiation passing across the intermediate focal plane 16 is guided into an object plane 12 by the illumination system 10, with the result that an object field in the object plane 12 is illuminated with uniform radiation intensity.

The illumination system 10 comprises a deflection mirror 17 which is used to deflect the exposure radiation to a first facet mirror 18. A second facet mirror 19 is disposed downstream of the first facet mirror 18. The second facet mirror 19 is used to image the facets of the first facet mirror 18 in the object plane 12.

A photomask 13 which is imaged in an image plane 21 by way of a plurality of mirrors M1-M6 of the projection lens 22 is arranged in the object plane 12. A structure formed on the photomask 13 is transferred to a radiation-sensitive layer of a wafer 20 arranged in the image plane 21. The photomask 13 is suspended from a first scanning device 24, and the wafer 20 is at rest on a second scanning device 25 such that the wafer 20 can be exposed in a scanning procedure during which the photomask 13 and the wafer 20 are moved synchronously with one another.

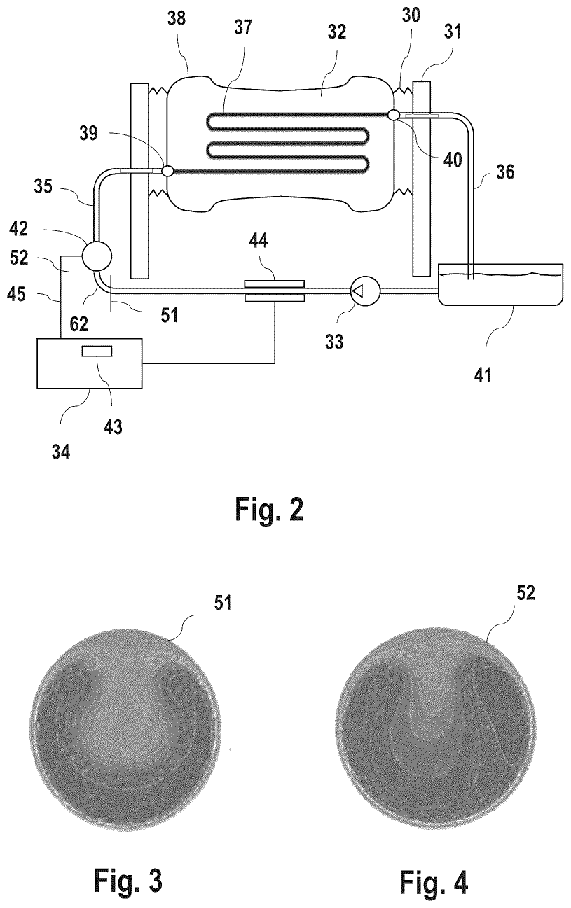

FIG. 2 shows a mirror device, in which a mirror body 38 of a mirror M1-M6 is held on a frame structure 31 via actuators 30. The actuators 30 can be used to modify the position of the mirror body 38 in relation to the frame structure 31 for the purpose of aligning and positioning the mirror body 38. An optical surface 32 at which EUV radiation is reflected is formed on the mirror body 38. Each mirror M1-M6 of the projection lens 22 from the projection exposure apparatus of FIG. 1 is in the form of a mirror device according to FIG. 2. It is also possible to equip only some of the mirrors M1-M6 in this way.

A fluid channel in the form of a cooling channel 37, which extends through the mirror body 38 along a meandering path, is formed in the interior of the mirror body 38. The cooling channel 37 is part of a cooling system in which a temperature control fluid is conveyed along a closed cooling circuit via a pump 33. The temperature control fluid is a cooling liquid in the present exemplary embodiment.

The cooling circuit extends from the pump 33 through a feed line 35 to the cooling channels 37 and, through a return line 36, back to a storage container 41, from where the cooling liquid is aspirated by the pump 33. The feed line 35 is connected to the mirror body 38 via an input connector 39; the return line 36 is connected to the mirror body 38 via an output connector 40. The feed line 35 and the return line 36 have sufficient flexibility so that adjustment and alignment of the mirrors is not impeded. The coolant takes up heat arising due to the absorbed EUV radiation and removes it from the mirror body 38.

The mirror system comprises a control unit 34 which controls the mirror system operation on the basis of various input parameters, wherein control signals inter alia influence the thermal state of the mirror body 38. One aspect here is that the control unit 34 is provided with a target value for the temperature at which the cooling liquid enters the mirror body 38. The target value is stored in a memory module 43 of the control unit 34.

The feed line 35 is provided with a temperature sensor 42 which transmits measured temperature values to the control unit 34 via a control line 45. The control unit 34 creates control signals, which are used to control a temperature control unit 44, on the basis of a comparison between the measured temperature value and the target value stored in the memory module 43. The temperature control unit 44 extends over the circumference of the feed line 35 and can either supply heat to or withdraw heat from the cooling liquid in the feed line 35 depending on the comparison between the measured temperature value and the target value, with the result that the cooling liquid is heated or cooled. The actual temperature of the cooling liquid can be brought closer to the target temperature in this way.

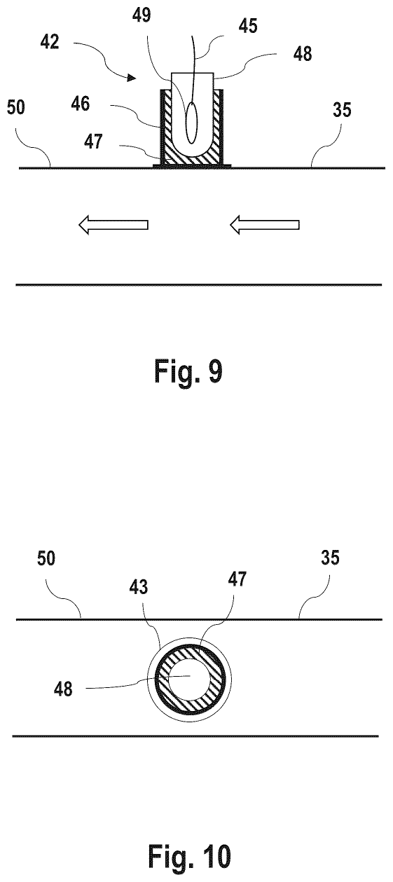

According to FIGS. 9 and 10, the temperature sensor 42 comprises a housing 46 which is adhesively bonded to the outside of the feed line 35. The housing 46 has an outwardly pointing opening, in which a sensor element 48 is inserted. The sensor element 48 comprises an NTC thermistor 49 which is arranged in a glass substrate and whose electrical resistance changes depending on the temperature. The sensor element 48 is thermally coupled to the housing 46 by way of a thermally conductive paste 47, and so heat is exchanged with the cooling liquid via the thermally conductive paste, the housing 46 and the tube wall 50. A change in the coolant temperature leads to a modified measured temperature value from the sensor element 48. The modified measured temperature value is transmitted to the control unit 34 via the control line 45.

Arranging the temperature sensor 42 on the outside of the tube wall 50 of the feed line 35 prevents the coolant flow state being modified by the temperature sensor 42. The coolant can propagate along the feed line 35 as if no temperature sensor 42 were present. For example, this prevents the temperature sensor 42 leading to the possible creation of turbulence in the coolant flow.

In this configuration, the measured value obtained by the temperature sensor 42 depends on the fact that heat is transferred between the cooling liquid and the sensor element 48 through the tube wall 50, the housing 46 and the thermally conductive paste 47. With regards to the cross section of the feed line 35, components of the cooling liquid adjacent to the temperature sensor 42 make a greater contribution to the measured temperature value than components of the cooling liquid distant from the temperature sensor 42.

The temperature distribution of the cooling liquid over the cross section of the feed line 35 varies over the length of the feed line 35. The temperatures of the tube wall and peripheral components of the cooling liquid equalize following a relatively long section of laminar flow, while a temperature gradient between the periphery and the centre sets in within the cooling liquid.

FIG. 3 shows the temperature distribution across the cross section of the feed line 35 at a position 51 (see FIG. 2) where the cooling liquid has passed through a long straight section of the feed line 35, and so the temperature in the centre deviates significantly from the temperature at the periphery. At a position 52, after the cooling liquid has followed a deflection 62 in the feed line 35, the cooling liquid has undergone a mixing process over its cross section, and so the temperature gradient is significantly lower. The temperature distribution at position 52 is shown in FIG. 4. According to the disclosure, the temperature sensor 42 is arranged close to the position 52 so that a measured temperature value obtained via the cooling liquid periphery is significantly closer to a mean temperature of the cooling liquid over the cross section of the feed line 35 than at the position 51.

According to FIG. 3, the temperature gradient at this position is smaller but has not disappeared completely. According to the disclosure, provision is made for a first correction calculation to be performed on the basis of the measured temperature value obtained by the temperature sensor 42, in order to obtain a temperature value for the average temperature of the cooling liquid over the cross section of the feed line 35. A table allowing corrected temperature values to be read for various measured temperature values can be stored in the memory module 43 of the control unit 34.

A second correction calculation is performed because the temperature sensor 42 is arranged at a distance from the mirror body 38. Thus, the cooling liquid passes over a length of feed line 35 before entering the mirror body 38, and this has a further influence on the cooling liquid temperature. This influence is modelled using the second correction calculation, and so information about the cross section-related average cooling liquid temperature upon entry in the mirror body 38 is obtained from the measured temperature values of the temperature sensor 42. A table from which the relevant correction values can be read can also be stored in the memory module 43 of the control unit 34 in the context of the second correction calculation.

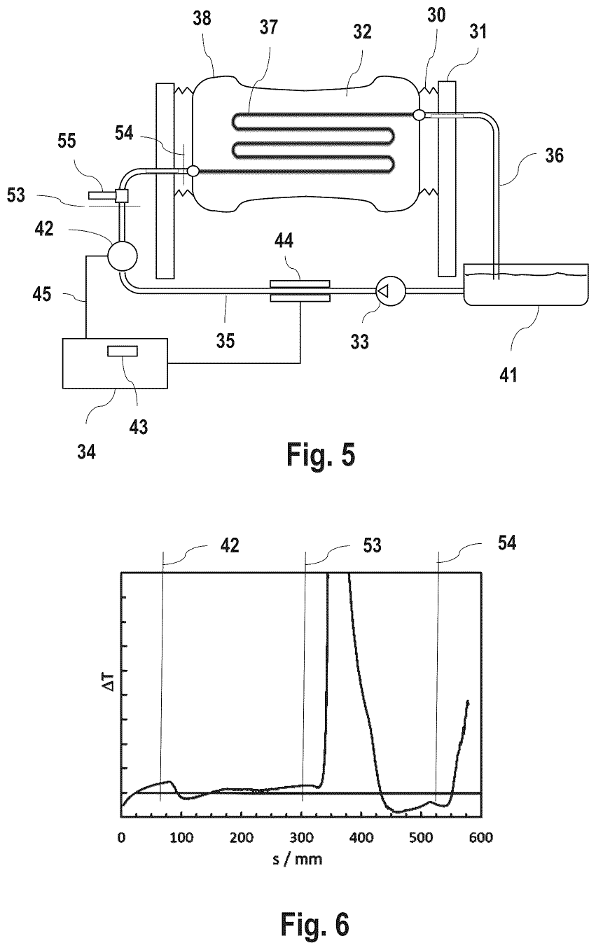

FIG. 5 shows an alternative embodiment of a mirror system according to the disclosure, in which the feed line 35 is held using a tube clamp 55. The tube clamp 55 comprises a sleeve which extends over the circumference of the feed line 35 and rests on the tube wall 50 of the feed line 35. FIG. 6 plots, in relative units, the temperature difference ΔT between the tube wall 50 and the temperature of the cooling liquid in a region adjacent to the tube wall 50. The horizontal axis corresponds to different positions along the extent of the feed line 35.

It is evident that the tube clamp 55 forms a significant heat bridge and there is a significant increase in the temperature difference ΔT downstream of position 53 as a result. Downstream of the tube clamp 55, the temperature difference ΔT drops again and is close to the value upstream of the tube clamp 55. There is another increase in the temperature difference ΔT downstream of position 54 because the mirror body 38 itself acts as a heat store. According to the disclosure, the temperature sensor 42 is arranged at a distance from heat-conducting structures such as tube clamps or the mirror body 38, for example, in order to prevent a falsification of the measurement results due to heat bridges to the greatest possible extent. Unlike conventional designs, the disclosure thus does not provide for a tube clamp 55 to be used as a support structure for a temperature sensor at the same time.

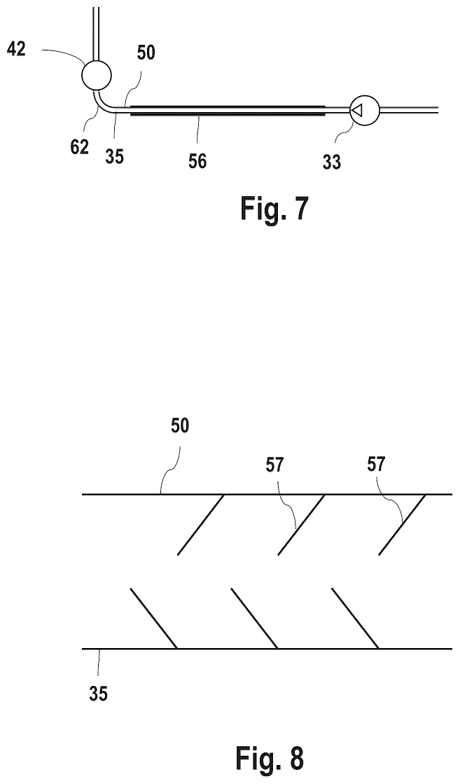

FIG. 7 shows a detail of the feed line 35 in an alternative embodiment of the disclosure. A section of the feed line 35 arranged between the pump 33 and the temperature sensor 42 is provided with a thermal insulation 56. The thermal insulation 56 is designed such that it causes no outgassing under the vacuum conditions found in the microlithographic projection exposure apparatus. The thermal insulation 56 leads to the tube wall 50 having substantially the same temperature as the adjacent cooling fluid components. There is a reduction in the temperature gradient over the cross section of the feed line 35.

In addition to the thermal insulation 56 or as an alternative, the feed line 35 can be provided with a static mixer; see FIG. 8. The static mixer consists of mixing structures 57 which protrude into the interior of the feed line 35 from the tube wall 50. The mixing structures 57 are designed so that the cooling liquid is mixed over its cross section without turbulence arising. Static mixers of this type are known from the chemical industry.

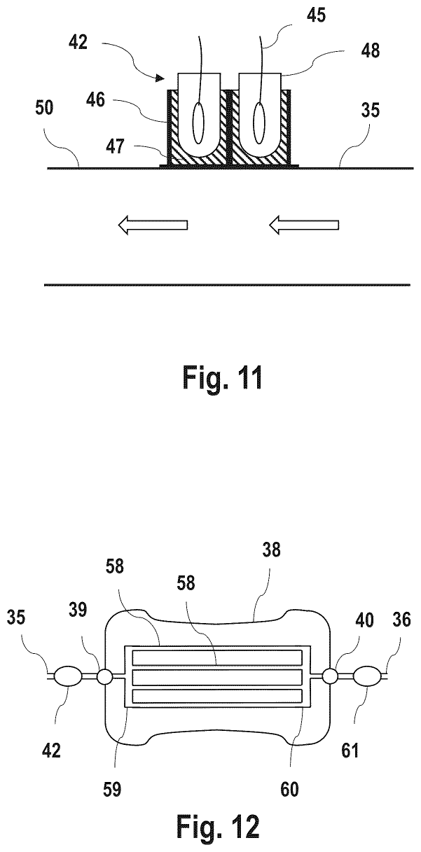

FIG. 11 shows an alternative embodiment, in which the housing 46 of the temperature sensor 42 comprises two receptacles for sensor elements 48. The two sensor elements 48 are operated in a master/slave configuration, and so the measured values of the second sensor element 48 are only processed in the control unit 34 if the first sensor element 48 suffers an outage. This redundancy increases the operational reliability of the mirror system.

In the exemplary embodiment according to FIG. 12, the mirror body 38 has a plurality of cooling channel portions 58 which are parallel to one another and extend between an input manifold 59 and an output manifold 60. The temperature sensor 42 is arranged in the feed line 35 at a distance from the input manifold 59 so that the measured values obtained by the temperature sensor 42 are not falsified by the input manifold 59. A second temperature sensor 61 is arranged in the return line 36, likewise at a distance from the output manifold 60. The quantity of heat absorbed in the mirror body 38 can be deduced from the difference between the measured temperature values obtained by the temperature sensors 42, 61, and this in turn forms a measure for the degradation of the optical surface 32 on the mirror body 38 provided the thermal load from the EUV radiation is constant. The measured values can be processed within the scope of predictive maintenance methods.

What is claimed is:

1. A mirror system, comprising:
an EUV mirror comprising an EUV reflective optical surface;
a structure body supporting the EUV reflective optical surface;
a fluid channel configured to have a fluid flow therethrough, the fluid channel extending in the structure body;
a feed line configured to supply the fluid to the fluid channel; and
a temperature sensor configured to sense a temperature of the fluid in a portion of the feed line,
wherein the temperature sensor is outside of a cross section of the feed line.

2. The mirror system of claim 1, wherein the structure body comprises a mirror body of the EUV mirror.

3. The mirror system of claim 1, wherein the EUV mirror further comprises a mirror body supporting the EUV reflective optical surface, and the structure body supports the mirror body.

4. The mirror system of claim 1, wherein the feed line comprises a tube wall, and the tube wall is not interrupted in a region of the temperature sensor.

5. The mirror system of claim 4, wherein the temperature sensor comprises a sensor element in physical contact with the tube wall.

6. The mirror system of claim 5, wherein, in a region of the temperature sensor, the feed line has a circumferential portion of at least 180° in which the temperature sensor is not in contact with the tube wall.

7. The mirror system of claim 5, wherein the temperature sensor comprises a housing adhesively bonded to the tube wall.

8. The mirror system of claim 1, wherein the temperature sensor is in a portion of the feed line in which a temperature gradient over the cross section of the feed line is small.

9. The mirror system of claim 1, wherein the feed line comprises a deflection, and the temperature sensor is less than 10 centimeters downstream of the deflection.

10. The mirror system of claim 1, wherein, as measured along the feed line, a distance between the temperature sensor and a closest heat-conducting structure is greater than 20 millimeters.

11. The mirror system of claim 1, wherein a portion of the feed line comprises a thermal insulation.

12. The mirror system of claim 1, further comprising a static mixer in the feed line upstream of the temperature sensor.

13. The mirror system of claim 1, further comprising a control unit configured to:
process measured temperature values recorded by the temperature sensor and/or corrected temperature values derived from the measured temperature values; and
generate control signals to control the operation of the mirror system.

14. The mirror system of claim 1, wherein the feed line comprises a tube wall, the tube wall is not interrupted in a region of the temperature sensor, the feed line comprises a deflection, and the temperature sensor is less than 10 centimeters downstream of the deflection.

15. The mirror system of claim 1, wherein:
the feed line comprises a tube wall;
the tube wall is not interrupted in a region of the temperature sensor; and
as measured along the feed line, a distance between the temperature sensor and a closest heat-conducting structure is greater than 20 millimeters.

16. The mirror system of claim 1, wherein the feed line comprises a tube wall, the tube wall is not interrupted in a region of the temperature sensor, and a portion of the feed line comprises a thermal insulation.

17. The mirror system of claim 1, wherein:
the feed line comprises a deflection;
the temperature sensor is less than 10 centimeters downstream of the deflection; and
as measured along the feed line, a distance between the temperature sensor and a closest heat-conducting structure is greater than 20 millimeters.

18. A lens, comprising:
a mirror system according to claim 1,
wherein the lens is a projection lens.

19. An apparatus, comprising:
a projection lens comprising a plurality of EUV mirrors configured to image a mask into an image plane,
wherein at least one of the EUV mirrors is an EUV mirror of a mirror system according to claim 1, and the apparatus is a microlithographic projection exposure apparatus.

20. A method of operating a mirror system, the mirror system comprising an EUV mirror comprising an EUV reflective optical surface, the mirror system further comprising a structure body supporting the EUV reflective optical surface, the method comprising:
using a feed line to provide a fluid to a channel in the structure body so that the fluid flows through the channel; and
using a temperature sensor to record a temperature value of the fluid in a portion of the feed line,
wherein the temperature sensor is outside of a cross section of the feed line.
